(19) United States
(12) Patent Application Publication
(10) Pub. No.: US 2014/0272465 A1
(43) Pub. Date: Sep. 18, 2014

(54) METHOD OF HEAT TREATMENT OF SILVER LAYERS

(71) Applicant: SAINT-GOBAIN GLASS FRANCE, Courbevoie (FR)

(72) Inventors: Fabien Lienhart, Paris (FR); Martin Python, Vesin (CH)

(73) Assignee: SAINT-GOBAIN GLASS FRANCE, Courbevoie (FR)

(21) Appl. No.: 14/352,903

(22) PCT Filed: Oct. 18, 2012
(86) PCT No.: PCT/FR2012/052368

§ 371 Date: Apr. 18, 2014

(30) Foreign Application Priority Data
Oct. 18, 2011 (FR) 11 59389

(51) Int. Cl. C23C 14/58; C23C 14/18; C23C 14/35

(52) U.S. Cl. CPC C23C 14/5806; C23C 14/35; C23C 14/18
USPC 428/673; 427/559; 204/192.15

(57) ABSTRACT

The subject of the invention is a process for obtaining a material comprising a substrate coated on at least one portion of at least one of its faces with a stack of thin layers comprising at least one silver layer, said process comprising a step of depositing said stack then a heat treatment step, said heat treatment being carried out by irradiating at least one portion of the surface of said stack using at least one incoherent light source for an irradiation time ranging from 0.1 millisecond to 100 seconds, so that the sheet resistance and/or the emissivity of said stack is reduced by at least 5% in relative terms, the or each silver layer remaining continuous at the end of the treatment.

The invention relates to the heat treatment of silver layers deposited on a substrate.

The silver layers, due to their optical properties, in particular of reflection of infrared radiation, and/or due to their electron conduction properties, are particularly valued and used in very diverse applications: low-emissivity or solar-control layers used in glazing units, heating layers for electrically heated glazing units or radiators, or else electrodes, for example used in organic light-emitting diode devices (OLED devices).

An OLED is a device which emits light by electroluminescence using the recombination energy of holes injected from an anode and of electrons injected from a cathode. It comprises an organic light-emitting material, or a stack of organic light-emitting materials, flanked by two electrodes, one of the electrodes, referred to as the bottom electrode, generally the anode, consisting of the one associated with the substrate and the other electrode, referred to as the top electrode, generally the cathode, being arranged on the organic light-emitting system.

Various OLED configurations exist:
bottom emission devices, that is to say devices with a (semi) transparent bottom electrode and a reflective top electrode;
top emission devices, that is to say devices with a (semi) transparent top electrode and a reflective bottom electrode;
top and bottom emission devices, that is to say devices with both a (semi) transparent bottom electrode and a (semi) transparent top electrode.

An OLED device generally finds its application in a display screen or a lighting device. The bottom electrodes must have the lowest possible resistivity, the highest possible optical transmission, and be particularly smooth: an RMS roughness of at most 2 nm, or even 1 nm is often necessary. As electrode, it is possible to use an electrically conductive stack of thin layers, in particular a stack comprising at least one silver layer.

The silver layers are also frequently used in glazing units intended to improve thermal comfort: low-emissivity glazing units (which limit the heat losses to the outside and consequently increase the energy efficiency of the buildings which are equipped therewith) or solar-control glazing units (which limit the heat gains in the rooms of a building or in the passenger compartments of motor vehicles). These layers are, for example, located on face 2 or 3 of double glazing units.

Whatever the application, and in order in particular to prevent the oxidation of the silver and to attenuate its reflection properties in the visible spectrum, the or each silver layer is generally inserted into a stack of layers. The or each thin silver-based layer may be placed between two thin dielectric layers based on oxide or nitride (for example made of SnO₂ or Si₃N₄). A very thin layer, intended to promote the wetting and nucleation of the silver (for example made of zinc oxide ZnO), may also be placed under the silver layer and a second very thin layer (sacrificial layer, for example made of titanium), intended to protect the silver layer in case the deposition of the subsequent layer is carried out in an oxidizing atmosphere or in the event of heat treatments that result in a migration of oxygen within the stack, may also be placed on the silver layer. These layers are respectively referred to as a wetting layer and a blocker layer. The stacks may also comprise several silver layers.

The silver layers have the distinctive feature of seeing their resistivity and emissivity be improved when they are in an at least partially crystallized state. It is generally sought to increase as much as possible the degree of crystallization of these layers (the proportion by weight or by volume of crystallized material) and the size of the crystalline grains (or the size of coherent diffraction domains measured by X-ray diffraction methods).

In particular, it is known that the silver layers having a high degree of crystallization and consequently a low residual content of amorphous silver have a lower resistivity and a lower emissivity and also a higher transmission in the visible spectrum than predominantly amorphous silver layers. The electrical conductivity of these layers is thus improved, as are the low-emissivity properties. The increase in the size of the grains is indeed accompanied by a reduction in the grain boundaries, favorable to the mobility of electric charge carriers.

One process commonly used on an industrial scale for depositing thin layers of silver onto a glass or polymer substrate is the magnetron sputtering process. In this process, a plasma is created under a high vacuum in the vicinity of a target comprising the chemical elements to be deposited, in this case silver. The active species of the plasma, by bombarding the target, tear off said elements, which are deposited on the substrate, forming the desired thin layer. This process is said to be “reactive” when the layer consists of a material resulting from a chemical reaction between the elements torn off from the target and the gas contained in the plasma. The major advantage of this process lies in the possibility of depositing, on one and the same line, a very complex stack of layers by successively making the substrate pass under various targets, this generally being in one and the same device.

During the industrial implementation of the magnetron process, the substrate remains at ambient temperature or is subjected to a moderate temperature rise (less than 80° C.), particularly when the run speed of the substrate is high (which is generally desired for economic reasons). What may appear to be an advantage however constitutes a disadvantage in the case of the aforementioned layers, since the low temperatures involved do not generally allow sufficient crystalline growth. This is the case, very particularly, for thin layers of small thickness and/or layers consisting of materials having a very high melting point. The layers obtained according to this process are therefore predominantly or even completely amorphous or nanocrystalline (the mean size of the crystalline grains being of the order of a nanometer), and heat treatments prove to be necessary in order to obtain the desired degree of crystallization or the desired grain size, and therefore the desired low resistivity.

Possible heat treatments consist in reheating the substrate either during the deposition, or at the end of the deposition, for example on exiting the magnetron line. The crystallization is even better and the size of the grains is even larger when the temperature of the substrate is close to the melting point of the material constituting the thin film. But most generally, temperatures of at least 200° C. or 300° C. are necessary, which is not generally possible for organic substrates.

The heating of the substrate in industrial magnetron lines (during the deposition) has however proved to be difficult to implement, in particular because the heat transfers under vacuum, inevitably of radiative nature, are difficult to control and involve a high cost in the case of substrates of large size, having a width of several meters. In the case of thin glass substrates, this type of treatment often involves high breakage risks. In addition, the silver layers deposited on a hot substrate have a tendency to form discontinuous layers, in the form of islands, the resistivity of which is high.

Finally, the silver layers deposited on a hot substrate or a substrate that has undergone a subsequent heat treatment are particularly rough, which makes them unsuitable for use as an electrode of an OLED device.

The heating of the coated substrate at the end of the deposition, for example by placing the substrate in a furnace or an oven or by subjecting the substrate to infrared radiation resulting from conventional heating devices such as infrared lamps, also has disadvantages because these various processes contribute to indiscriminately heating the substrate and the thin layer. The heating of the substrate at temperatures greater than 150° C. is capable of generating breakages in the case of substrates of large size (with a width of several meters) since it is impossible to ensure an identical temperature over the whole of the width of the substrate. The heating of the substrates also slows down the whole of the process, since it is necessary to wait for the complete cooling thereof before contemplating the cutting thereof or the storage thereof, which generally takes place by stacking the substrates on top of one another. A highly controlled cooling is moreover essential in order to prevent the generation of stresses within the glass, and therefore the possibility of breakages. Since such a highly controlled cooling is very expensive, the annealing is not generally sufficiently controlled to eliminate the thermal stresses within the glass, which generates an increased number of in-line breakages. The annealing also has the disadvantage of making the cutting of the glass more difficult, the cracks having a lesser tendency to propagate linearly. It has also been observed that the conventional annealings generated defects in the silver layer, in the form of “dendrites”, probably due to the migration of oxygen into the layer, and that are particularly detrimental in OLED applications.

Heating of the coated substrates takes place in the case where the glazing units are curved and/or tempered, since a reheating of the glass beyond its softening point (generally at more than 600° C., or even 700° C. for several minutes) is carried out. The tempering or bending therefore makes it possible to obtain the desired result of crystallization of the thin layers. It would however be expensive to submit all the glazing units to such treatments for the sole purpose of improving the crystallization of the layers. Moreover, the toughened glazing units can no longer be cut, and certain stacks of thin layers do not withstand the high temperatures undergone during the tempering of the glass.

It is also known from applications WO 2008/096089 and WO 2010/142926 to heat treat stacks containing one or more silver layers using, for example, a flame or a laser radiation. In order to do this, the substrate coated with the silver layer passes under a burner or under a laser line so as to treat the whole of the surface. These processes are not however without disadvantages because they may generate mechanical stresses within the layer, capable of leading, in certain cases, to a delamination thereof.

The invention proposes to overcome all of these disadvantages, by providing a process for obtaining a material comprising a substrate coated on at least one portion of at least one of its faces with a stack of thin layers comprising at least one silver layer, said process comprising a step of depositing said stack then a heat treatment step, said heat treatment being carried out by irradiating at least one portion of the surface of said stack using at least one incoherent light source for an irradiation time ranging from 0.1 millisecond to 100 seconds, so that the sheet resistance and/or the emissivity of said stack is reduced by at least 5% in relative terms, the or each silver layer remaining continuous at the end of the treatment.

Such a heat treatment makes it possible to reduce the resistivity or the emissivity of the silver layer (generally both properties), may be carried out on substrates made of a polymeric material, and does not generate defects of dendrite type or delamination.

The term “light” is understood to mean electromagnetic radiation that covers not only visible light, but also the ultraviolet and infrared ranges. The wavelengths emitted by the light source are typically within a range extending from 200 nm to 3 μm. The light used will generally be able to be broken down into a discrete or continuous spectrum of several wavelengths.

The heat treatment is preferably carried out by simultaneously irradiating a portion of the surface of the stack, the smallest side of which has a length of at least 1 cm, in particular 5 cm, or 10 cm and even 30 or 50 cm.

The simultaneously irradiated surface preferably represents at least 10%, or 20%, or even 50% of the total surface of the stack. In order to treat the whole of the surface, it is then possible to successively treat the various portions using one and the same light source, by providing a relative displacement between the light source and the substrate. By way of example, the or each light source may be fixed, the substrate running past it. Alternatively, the substrate may be fixed and the light source may be moved past the substrate.

In certain cases, the heat treatment is preferably carried out by simultaneously irradiating the whole of the surface of the stack. This is in particular the case for substrates having a surface of at most 1 or 2 m², by using, for example, a single light source, or for substrates of any size, using several light sources.

The improvement in the crystallization characteristics of the silver due to the heat treatment also makes it possible to improve the light transmission of the coated substrate, by at least 1%, in particular 2% in absolute terms (it is not a relative increase). The light transmission is calculated according to the NF EN 410 standard.

Preferably, the sheet resistance and/or the emissivity is reduced by at least 10%, or 15% or even 20% by the heat treatment. Here this is a relative reduction, with respect to the value of the sheet resistance or of the emissivity before treatment.

The substrate is preferably made of glass or made of a polymeric organic material. It is preferably transparent, colorless (it is then a clear or extra-clear glass) or tinted, for example tinted blue, gray or bronze. The glass is preferably of soda-lime-silica type, but it may also be made of glass of borosilicate or alumino-borosilicate type. The preferred polymeric organic materials are polycarbonate, polymethyl methacrylate, polyethylene terephthalate (PET), polyethylene naphthalate (PEN), or else fluoropolymers such as ethylene tetrafluoroethylene (ETFE). The substrate advantageously has at least one dimension of greater than or equal to 1 m, or 2 m and even 3 m. The thickness of the substrate generally varies between 0.025 mm and 19 mm, preferably between 0.4 and 6 mm, in particular between 0.7 and 2.1 mm for a glass substrate, and preferably between 0.025 and 0.4 mm, in particular between 0.075 and 0.125 mm for a polymer substrate. The substrate may be flat or curved, or even flexible.

The glass substrate is preferably of float glass type, that is to say capable of having been obtained by a process that consists in pouring the molten glass onto a bath of molten tin (“float” bath). In this case, the layer to be treated may just as well be deposited on the “tin” side as on the “atmosphere” side of the substrate. The terms “atmosphere side” and “tin side” are understood to mean the faces of the substrate that have respectively been in contact with the atmosphere in the float bath and in contact with the molten tin. The tin side contains a small amount of tin on the surface that has diffused into the structure of the glass. The glass substrate may also be obtained by rolling between two rolls, which technique makes it possible in particular to imprint patterns on the surface of the glass.

According to a first preferred embodiment, the or each light source comprises at least one flash lamp, in particular an argon or xenon flash lamp, the irradiation time ranging from 0.1 to 20 milliseconds, in particular from 0.5 to 5 milliseconds. Such lamps are generally in the form of sealed glass tubes filled with a noble gas, typically xenon, argon, helium or krypton, provided with electrodes at their ends. Under the effect of an electric pulse of short duration, obtained by discharge of a capacitor, the gas ionizes and produces a particularly intense incoherent light. The emission spectrum generally comprises at least two emission lines. The capacitor is typically charged to a voltage of 500 to 5000 V. The total energy density emitted by the flash lamps, relative to the surface area of the layer, is preferably between 1 and 100 J/cm², in particular between 5 and 30 J/cm², in particular between 10 and 20 J/cm². The consequence of the very short irradiation times is that only the extreme surface of the material is heated, which has a very distinct advantage, particularly when the substrate is made of a polymeric material.

According to a second preferred embodiment, the or each light source comprises at least one halogen incandescent light, the irradiation time ranging from 0.1 to 100 seconds, in particular from 1 to 30 seconds. The lamps are typically in the form of glass tubes containing a tungsten filament and a halogen gas, such as iodine and/or bromine, at high pressure. The temperature reached by the material is preferably between 400° C. and 700° C., in particular between 500° C. and 650° C. The temperature rise is very rapid, with a rate ranging from 10 to 150° C./s, before reaching a hold. The increase in temperature of the substrate may be reached more rapidly by placing said substrate on a support that absorbs the light emitted by the lamp, for example a graphite support.

The stack, before or after heat treatment, preferably comprises at least one silver layer between at least two layers.

The stack preferably comprises, starting from the substrate, a first coating comprising at least one first dielectric layer, at least one silver layer, optionally an overblocker layer, and a second coating comprising at least a second layer, in particular a dielectric layer. In particular, when the substrate is made of a polymeric organic material, which is for example flexible, or when the substrate is combined with a lamination interlayer, the first and second coatings advantageously act as a barrier layer to moisture and to gases.

Preferably, the physical thickness of at least one, in particular of the or of each silver layer, is between 6 and 20 nm.

The overblocker layer is intended to protect the silver layer during the deposition of a subsequent layer (for example if the latter is deposited under an oxidizing or nitriding atmosphere) and during an optional subsequent heat treatment.

The silver layer may also be deposited on and in contact with an underblocker layer. The stack may therefore comprise an overblocker layer and/or an underblocker layer flanking the or each silver layer.

Blocker (underblocker and/or overblocker) layers are generally based on a metal chosen from nickel, chromium, titanium, niobium or an alloy of these various metals. Mention may in particular be made of nickel-titanium alloys (especially those comprising around 50% by weight of each metal) or nickel-chromium alloys (especially those comprising 80% by weight of nickel and 20% by weight of chromium). The overblocker layer may also consist of several superposed layers; for example, on moving away from the substrate, a titanium layer and then a nickel alloy (especially a nickel-chromium alloy) layer, or vice versa. The various metals or alloys mentioned may also be partially oxidized, and may especially be oxygen substoichiometric (for example TiOₓ or NiCrOₓ).

These blocker (underblocker and/or overblocker) layers are very thin, normally having a thickness of less than 1 nm, so as not to affect the light transmission of the stack, and can be partially oxidized during the heat treatment according to the invention. In general, the blocker layers are sacrificial layers, capable of capturing oxygen coming from the atmosphere or from the substrate, thus preventing the silver layer from oxidizing.

The first dielectric layer is typically an oxide (especially tin oxide), or preferably a nitride, especially silicon nitride. In general, the silicon nitride may be doped, for example with aluminum or boron, so as to make it easier to deposit by sputtering techniques. The degree of doping (corresponding to the atomic percentage relative to the amount of silicon) generally does not exceed 10%. The function of the first dielectric layer is to protect the silver layer from chemical or mechanical attack and it also influences the optical properties, especially in reflection, of the stack, through interference phenomena.

The first coating may comprise one dielectric layer or several, typically 2 to 3, dielectric layers. The second coating may comprise one dielectric layer, or several, typically 2 to 3, dielectric layers. These dielectric layers are preferably made of a material chosen from the optionally doped oxides and/or nitrides of silicon, titanium, tin, zinc, magnesium, or any of their mixtures or solid solutions, for example a tin zinc oxide, or a titanium zinc oxide. The physical thickness of the dielectric layer, or the overall physical thickness of all the dielectric layers, is preferably between 15 and 300 nm, in particular between 20 and 200 nm.

The first coating preferably comprises, immediately beneath the silver layer or beneath the optional underblocker layer, a wetting layer, the function of which is to increase the wetting and bonding of the silver layer. Zinc oxide, especially when doped with aluminum, proves to be particularly advantageous in this regard.

The first coating may also contain, directly beneath the wetting layer, a smoothing layer, which is a mixed oxide and/or nitride that is partially or completely amorphous (therefore having a very low roughness), the function of which is to promote the growth of the wetting layer in a preferential crystallographic orientation, thereby promoting silver crystallization through epitaxial phenomena. The smoothing layer is preferably composed of a mixed oxide of at least two metals chosen from Sn, Zn, In, Ga, Sb and Si. A preferred oxide is antimony-doped tin zinc oxide, or a zirconium-doped and aluminum-doped silicon nitride.

In the first coating, the wetting layer or the optional smoothing layer is preferably deposited directly on the first dielectric layer. The first dielectric layer is preferably deposited directly on the substrate. For optimally adapting the optical properties (especially the appearance in reflection) of the stack, the first dielectric layer may as an alternative be deposited on another oxide or nitride layer, for example a titanium oxide or silicon nitride layer.

Within the second coating, the second layer is preferably conductive for OLED applications and preferably dielectric for the other applications. The second dielectric layer is typically an oxide (especially tin oxide), or preferably a nitride, especially silicon nitride.

The second layer, whether it is dielectric or not, may be deposited directly on the silver layer, or preferably on an overblocker, or else on other oxide or nitride layers, intended for adapting the optical properties of the stack. For example, a zinc oxide layer, especially one doped with aluminum, or else a tin oxide layer, or tin zinc oxide layer, may be placed between an overblocker and the second layer. Zinc oxide, especially aluminum-doped zinc oxide, makes it possible to improve the adhesion between the silver and the upper layers.

Thus, the stack treated according to the invention preferably comprises at least one ZnO/Ag/ZnO sequence. The zinc oxide may be doped with aluminum. An underblocker layer may be placed between the silver layer and the subjacent layer. Alternatively or additionally, an overblocker layer may be placed between the silver layer and the subjacent layer.

Finally, the second coating may be surmounted by an overlayer intended to protect the stack from any mechanical attack (scratches, etc.) or chemical attack. This overlayer is generally very thin so as not to disturb the appearance in reflection of the stack (its thickness is typically between 1 and 5 nm). It is preferably based on titanium oxide or mixed tin zinc oxide, especially one doped with antimony, deposited in substoichiometric form.

When the stack is intended to be integrated into an OLED device, the last layer of the stack is preferably a transparent conductive oxide having a high work function, such as an oxide of indium and of at least one element chosen from tin and zinc (ITO, IZO, ITZO layers). In the general architecture described above, this last layer is part of the second coating and preferably corresponds to the “second layer”.

The stack may comprise one or more silver layers, in particular two or three silver layers. When several silver layers are present, the general architecture presented above may be repeated. In this case, the second coating relative to a given silver layer (therefore located on top of this silver layer) generally coincides with the first coating relative to the next silver layer.

A few nonlimiting examples of stacks that may be treated according to the invention are described below. The layers are indicated in the order of deposition starting from the substrate.

Stack 1: Si₃N₄/SnZnOₓ/ZnO/Ag/Ti/ITO

Stack 2: Si₃N₄/SnZnOₓ/ZnO/Ag/Ti/ZnO/SnZnOₓ/ZnO/Ag/Ti/ITO

These two stacks are particularly suitable for an application in an OLED device. The stack comprises a first coating comprising three layers, an overblocker and a second coating containing a second transparent and conductive layer, here made of ITO. Stack 2 illustrates a stack containing two silver layers.

The RMS roughness of the stack is preferably at most 2 nm, in particular 1 nm, both before and after treatment.

The materials coated with the stacks which follow are particularly well suited to integration into low-emissivity glazing.

Stack 3: Si₃N₄/TiO₂/(SnZnOₓ)/ZnO/Ag/Ti/ZnO/Si₃N₄/Ti

Stack 4: TiO₂/ZnO/Ag/ZnO/(TiO₂)/Si₃N₄/ZnSn

Stack 5: (Si₃N₄)/TiO₂/(NiCr)/Ag/NiCr/(ZnO)/SnO₂

Stack 6: SiNₓ/ZnO/Ag/NiCr/ZnO/Si₃N₄

Stack 7: Si₃N₄/ZnO/Ag/Ti/ZnO/Si₃N₄/ZnO/Ag/Ti/ZnO/Si₃N₄

Stack 8: Si₃N₄/ZnO/Ag/Ti/ZnO/Si₃N₄/ZnO/Ag/Ti/ZnO/Si₃N₄/ZnO/Ag/Ti/ZnO/Si₃N₄

The or each light source may be integrated into a layer deposition line, for example a magnetron sputtering deposition line or a chemical vapor deposition (CVD) line, especially a plasma-enhanced (PECVD) line, under vacuum or at atmospheric pressure (AP-PECVD). In general, the line includes substrate handling devices, a deposition unit, optical control devices and stacking devices. For example, the substrates run on conveyor rollers, in succession past each device or each unit.

The or each light source is preferably located just after the layer deposition unit, for example at the exit of the deposition unit. The coated substrate may thus be treated in line after the layer has been deposited, at the exit of the deposition unit and before the optical control devices, or after the optical control devices and before the substrate stacking devices.

The or each light source may also be integrated into the deposition unit. For example, it may be introduced into one of the chambers of a sputtering deposition unit, in particular into a chamber where the atmosphere is rarified, especially at a pressure between 10⁻⁶ mbar and 10⁻² mbar. The or each light source may also be placed outside the deposition unit, but so as to treat a substrate located inside said unit. For this purpose, all that is required is to provide a window transparent to the wavelengths of the radiation used, through which the light passes to treat the layer. The window is preferably made of a material having a low thermal expansion. It is thus possible to treat a layer (for example a silver layer) before the subsequent deposition of another layer in the same unit. When an absorbent layer is an overlayer, for example made of metal, its oxidation during the treatment may be impeded if the substrate is placed in a vacuum chamber. It is possible in this case to treat the stack in a special chamber, in which the oxidizing atmosphere is controlled.

Whether the radiation device is outside the deposition unit or integrated thereinto, these “in-line” processes are preferable to a process involving off-line operations, in which it would be necessary to stack the glass substrates between the deposition step and the heat treatment.

However, processes involving off-line operations may have an advantage in cases where the heat treatment according to the invention is carried out in a place different from that where the deposition is carried out, for example in a place where conversion of the glass takes place. The radiation device may therefore be integrated into lines other than the layer deposition line. For example, it may be integrated into a multiple glazing (especially double or triple glazing) manufacturing line, or into a laminated glazing manufacturing line. In these various cases, the heat treatment according to the invention is preferably carried out before the multiple glazing or laminated glazing is produced.

The stack may be deposited on the substrate by any type of process, in particular processes that generate predominantly amorphous or nanocrystalline layers, such as the sputtering process, in particular the magnetron sputtering process, the plasma-enhanced chemical vapor deposition (PECVD) process, the vacuum evaporation process or the sol-gel process.

The stack is preferably deposited by sputtering, in particular by magnetron sputtering.

For greater simplicity, the treatment of the layer is preferably carried out in air and/or at atmospheric pressure. However, it is possible for the heat treatment of the layer to be carried out within the actual vacuum deposition chamber, for example before a subsequent deposition. The treatment may also be carried out under a controlled atmosphere (argon, nitrogen, oxygen, etc.).

The process according to the invention can be carried out on a substrate placed both horizontally and vertically. It may also be carried out on a substrate provided with thin layers on both its faces, at least one layer of one of the faces or of each face being treated according to the invention. In the case where thin layers deposited on both faces of the substrate are treated according to the invention, it is possible to treat said thin layers of each face either simultaneously, or successively, by identical or different techniques, in particular depending on whether the nature of the treated layers is identical or different. The case where the treatment according to the invention is carried out simultaneously on both faces of the substrate is therefore very clearly within the scope of the invention.

Another subject of the invention is a material capable of being obtained by the process according to the invention, and also a glazing or an OLED device comprising at least one material according to the invention.

Such glazing is preferably a multiple glazing, comprising at least two glass sheets separated by a gas-filled cavity, in which the stack is placed on a side in contact with said gas-filled cavity, in particular on side 2 relative to the outside (i.e. on the side of the substrate in contact with the outside of the building which is on the opposite side to the side facing toward the outside) or on side 3 (i.e. on the side of the second substrate starting from the outside of the building facing toward the outside).

The invention is illustrated with the aid of the following nonlimiting exemplary embodiments.

Deposited by sputtering onto a clear soda-lime-silica glass substrate sold by the applicant under the brand SGG Planilux® is a stack of thin layers Si₃N₄/SnZnOₓ/ZnO/Ag/Ti/ZnO/SnZnOₓ/ZnO/Ag/Ti/ITO.

The samples are placed under a network of argon flash lamps placed in a chamber, the inner walls of which reflect the light. Under the effect of an electrical discharge (maximum 2500 V), the substrate coated with its stack is subjected to an intense flash having a duration of 3 ms, the energy density of which may be regulated of the order of 10 to 25 J/cm².

Table 1 below indicates, as a function of the energy density:
the drop in light absorption, denoted by AA and expressed in %; this is an absolute variation,
the drop in sheet resistance, expressed as AR and expressed in %; here this is a relative variation.

TABLE 1

| | Energy | | |
|---|---|---|---|
| Ex. | (J/cm²) | ΔA (%) | ΔR (%) |
| A1 | 14 | −0.2 | −2 |
| A2 | 16 | −0.8 | −21 |
| A3 | 18 | −1.2 | −21 |
| A4 | 20 | −1.5 | −22 |
| A5 | 22 | −2.7 | −35 |

These results show that above around 15 j/cm², for an illumination time of 3 ms, the silver layers of the stack see their crystallization characteristics very substantially improved, which results both in a drop in sheet resistance (and therefore in resistivity) of the stack and in a reduction of the light absorption, therefore an increase in the light transmission.

Stacks of the same type were also heat treated using halogen incandescent lamps. In order to do this, the samples are placed on graphite supports, facing a network of halogen incandescent lamps placed in a chamber with reflective walls. The temperature of the support is measured using a pyrometer. The samples are subjected to a temperature rise ramp up to a given hold temperature T, which is maintained for a given time t.

Table 2 below indicates, for each example:
the temperature rise rate V, expressed in ° C./s,
the hold temperature T, expressed in ° C.,
the hold time at the hold temperature, denoted by t, expressed in seconds,
the increase in the light transmission factor (in absolute terms), denoted by ΔT and expressed in %,
the drop in sheet resistance, expressed as ΔR and expressed in %; here this is a relative variation.

TABLE 2

| | V | | | | |
|---|---|---|---|---|---|
| Ex. | (° C./s) | T (° C.) | t (s) | ΔT (%) | ΔR (%) |
| B1 | 20 | 500 | 30 | 1.1 | −10.2 |
| B2 | 20 | 600 | 30 | 1.0 | −10.1 |
| B3 | 20 | 600 | 60 | 1.4 | −10.6 |
| B4 | 35 | 700 | 30 | −0.7 | −8.3 |

By way of comparative example, a substrate provided with the stack described previously is subjected to a conventional annealing treatment by bringing the substrate to a temperature of 300° C. for 30 minutes. The treatment clearly has the effect of reducing the sheet resistance of the stack, but generates defects of dendrite type.

1. A process comprising:
depositing a stack of thin layers, comprising a silver layer, on at least a portion of a face of a substrate, then
heat treating the stack by irradiating at least one portion of a surface of the stack with an incoherent light source for an irradiation time of from 0.1 millisecond to 100 seconds, thereby reducing a sheet resistance and/or an emissivity of the stack by at least 5% in relative terms,
wherein the silver layer remains continuous at the end of the treatment.

2. The process of claim 1, wherein the heat treating comprises simultaneously irradiating a portion of the surface of the stack, the smallest side of which has a length of at least 1 cm.

3. The process of claim 1, wherein the heat treating comprises simultaneously irradiating the entire surface of the stack.

4. The process of claim 1, wherein the substrate comprises glass or a polymeric organic material.

5. The process of claim 1, wherein the light source comprises a flash lamp, and wherein the irradiation time is from 0.1 to 20 milliseconds.

6. The process of claim 1, wherein the light source comprises a halogen incandescent lamp, and wherein the irradiation time is from 0.1 to 100 seconds.

7. The process of claim 1, wherein the depositing the stack on the substrate comprises sputtering.

8. The process as of claim 1, wherein the stack of thin layers comprises, starting from the substrate:
a first coating comprising a first dielectric layer, a silver layer, and optionally an overblocker layer, and
a second coating comprising a second layer.

9. A material obtained by a process comprising the process of claim 1.

10. A glazing unit or OLED device comprising the material of claim 9.

11. The process of claim 2, wherein the heat treating comprises simultaneously irradiating a portion of the surface of the stack, the smallest side of which has a length of at least 5 cm.

12. The process of claim 5, wherein the irradiation time is from 0.5 to 5 milliseconds.

13. The process of claim 6, wherein the irradiation time is from 1 to 30 seconds.
